(19) United States
(12) Patent Application Publication
(10) Pub. No.: US 2014/0169114 A1
(43) Pub. Date: Jun. 19, 2014

(54) VOLATILE MEMORY DEVICES, MEMORY SYSTEMS INCLUDING THE SAME AND RELATED METHODS

(71) Applicant: Samsung Electronics Co., Ltd., Suwon-si (KR)

(72) Inventor: Chi-Sung OH, Gunpo-si (KR)

(73) Assignee: Samsung Electronics Co., Ltd., Suwon-si (KR)

(21) Appl. No.: 14/095,179

(22) Filed: Dec. 3, 2013

(30) Foreign Application Priority Data
Dec. 13, 2012 (KR) 10-2012-0145080

(51) Int. Cl. G11C 7/00

(52) U.S. Cl. CPC G11C 7/00
USPC 365/222

(57) ABSTRACT

A volatile memory device includes a memory cell array including a plurality of pages and a refresh control circuit. The refresh control circuit may adjust a refresh interval according to a refresh information signal and refreshes the plurality of pages according to the adjusted refresh interval while refreshing weak pages of the plurality of pages at least twice during a refresh period. Each of the weak pages may include at least a weak cell whose data retention time is shorter than a data retention time of normal cells, and the refresh information signal is based on a number of the weak pages. A memory controller and may generate auto refresh commands for volatile memory device(s) based on refresh information reflecting a number of weak pages of the volatile memory device(s). Systems and methods are also disclosed.

### CROSS-REFERENCE TO RELATED APPLICATION(S)

This application claims priority under 35 USC §119 to Korean Patent Application No. 10-2012-0145080, filed on Dec. 13, 2012, in the Korean Intellectual Property Office (KIPO), the contents of which are incorporated herein in its entirety by reference.

### BACKGROUND

1. Technical Field

Exemplary embodiments relate to memory devices, and more particularly to a volatile memory device and a memory controller controlling the same.

2. Discussion of the Related Art

A volatile memory device, such as a dynamic random access memory (DRAM), may perform a refresh operation to retain data stored in memory cells. If a memory cell has a retention time shorter than a set or selected refresh period (e.g., a refresh period defined in a standard), a row of memory cells including the memory cell is often replaced with a row of redundancy cells. As the size of a memory cell shrinks, the number of memory cells having retention times shorter than the set refresh period has increased. Accordingly, the number of rows of redundancy cells has increased in conventional volatile memory devices.

### SUMMARY

Some example embodiments provide a volatile memory device capable of adaptively adjusting refresh intervals.

Some example embodiments provide a memory system and memory controllers capable of adaptively adjusting refresh intervals. Related methods are also provided.

According to some embodiments, a volatile memory device may comprise a memory cell array including a plurality of pages; and a refresh control circuit configured to refresh the plurality of pages every refresh period by performing, during each refresh period, refresh operations at regular refresh intervals to corresponding selected ones of the plurality of pages, and configured to adjust the refresh interval according to a number of the plurality of pages identified as weak pages including at least a weak cell whose data retention time being shorter than a data retention time of normal cells, and configured to refresh the pages identified as weak pages at least twice during each refresh period.

A first page of the pages identified as weak pages may have a first address, the refresh control circuit may be configured to refresh the first page in response to the refresh control circuit generating a refresh address of one of the plurality of pages, and the first address may be the same as the refresh address except that the first address differs from the refresh address by at least one most significant bit (MSB).

The refresh control circuit may be configured to selectively invert the at least one MSB of a refresh address to provide a changed refresh address based on a first comparison of the first address and the refresh address and a second comparison of an abbreviated first address and an abbreviated refresh address, the abbreviated first address and the abbreviated refresh address respectively being the first address and refresh address without the corresponding at least one MSB.

The refresh control circuit may comprise a refresh pulse generator configured to generate a refresh pulse signal having a period corresponding to the refresh interval; a refresh counter configured to generate a refresh address by performing a counting operation in response to the refresh pulse signal; a plurality of comparing units each configured to compare a corresponding one of weak page addresses of the pages identified as weak pages and the refresh address to provide a corresponding first intermediate match signal and configured to compare a corresponding one of abbreviated weak page addresses and an abbreviated refresh address to provide a corresponding second intermediate match signal, each of the abbreviated weak page addresses being the corresponding weak page address without its at least one MSB, the abbreviated refresh address being the refresh address without its at least one MSB; an operation unit configured to provide a first match signal based on the first intermediate match signals and a second match signal based on the second intermediate match signals; a control signal generator configured to generate a halt signal that halts an operation of the refresh counter during the refresh period, based on the first match signal and the second match signal; and an address changing unit configured to selectively invert the at least one MSB of the refresh address to provide a changed refresh address.

The operation unit may comprise a first OR circuit to perform a logical OR operation on the first intermediate match signals to provide the first match signal and a second OR circuit to perform a logical OR operation on the second intermediate match signals to provide the second match signal.

The operation unit may provide the first match signal as a first match detected logic level when the at least one of the weak page addresses match with the refresh address and may provide the second match signal with second match detected logic level when at least one of the abbreviated weak page addresses matches with the abbreviated refresh address.

The control signal generator may be configured to enable the halt signal and to invert the at least one MSB of the refresh address to provide the changed refresh address when the first match signal is not the first match detected logic level and the second match signal is the second match detected logic.

The refresh counter may be configured to halt the counting operation when the halt signal is enabled and when the halt signal is disabled, the refresh counter is configured to restart the counting operation at a refresh address of the refresh counter when the halt signal was enabled.

The volatile memory device may also comprise a weak page register configured to store weak page addresses of the pages identified as weak pages; and a refresh information generator configured to generate a refresh information signal based on the number of the weak pages stored in the weak page register, wherein the refresh control circuit may be configured to adjust the refresh interval according to the refresh information signal.

The volatile memory device may comprise a bank address register configured to store information on a plurality of bank addresses of banks constituting the memory cell array, wherein the refresh control circuit may be configured to refresh the pages identified as weak pages at least twice during the refresh period in a bank corresponding to one of the bank addresses stored in the bank address register.

A memory system may comprise a first volatile memory device; and a memory controller configured to control the first volatile memory device, wherein the first volatile memory device may be configured to provide the memory controller with refresh information signal corresponding to a number of identified weak pages that include at least a weak cell whose data retention time is shorter than a data retention time of normal cells, wherein the memory controller may be configured to provide an auto refresh command to the first volatile memory device at regular refresh intervals over a refresh period and is configured to adjust the refresh interval according to the refresh information signal, and wherein the first volatile memory device may be configured to refresh the plurality of pages in response to auto refresh commands received during the refresh period while refreshing the identified weak pages of the plurality of pages at least twice during the refresh period.

The memory system of may further comprise a memory module including a plurality of volatile memory devices including the first volatile memory device, wherein each of the volatile memory devices may be configured to provide the memory controller with respective refresh information according to a number of identified weak pages of the corresponding volatile memory device.

The memory controller may be configured to provide each of the volatile memory devices with auto refresh commands at respective refresh intervals based on the corresponding refresh information provided to the memory controller by the corresponding volatile memory device.

The memory controller may be configured to provide the plurality of volatile memory devices with auto refresh commands at the same refresh interval.

The volatile memory devices may be configured to perform refresh operations at a timing responsive to the received auto refresh commands and are configured to skip an individual refresh operation based on the refresh information corresponding to the volatile memory device.

A memory controller may comprise a register configured to store refresh information from a first memory device, the refresh information reflecting a number of weak pages of the first memory device; a command generation circuit configured to generate auto refresh commands and periodically transmit an auto refresh command to the first memory device at a first refresh interval, the command generation circuit may be configured to determine a length of the first refresh interval in response to the refresh information.

The memory controller may be configured to communicate with a plurality of memory devices. The register may be configured to store refresh information of the plurality of memory devices, including the first memory device, reflecting a number of pages of the plurality of memory devices identified as weak pages, and, for each of the plurality of memory devices, the command generation circuit may be configured to generate and transmit auto refresh commands periodically at a refresh interval corresponding to the respective memory device and determined by the refresh information of the register corresponding to the respective memory device.

The register may be configured to store refresh information of a second memory device, the refresh information of the second memory device reflecting a number of weak pages of the second memory device, and the command generation circuit may be configured to periodically transmit an auto refresh command to the second memory device at a second refresh interval, the command generation circuit being configured to determine a length of the second refresh interval in response to the refresh information of the second memory device.

The first interval may be different from the second interval.

The memory controller may be configured to communicate with a plurality of memory devices, and the register may be configured to store refresh information of each of the plurality of memory devices, including the first memory device, the refresh information of each memory device reflecting a number of pages of the plurality of memory devices identified as weak pages of that memory device, and the command generation circuit ma be configured to generate and transmit auto refresh commands shared by the plurality of memory devices, the auto refresh commands being transmitted periodically at a refresh interval determined by the command generation circuit, and the refresh interval may be determined by the command generation circuit in response to the refresh information of each of the plurality of memory devices stored.

Accordingly, the interval of the auto refresh command or the self refresh interval may be adaptively adjusted based on the refresh information signal according to the number of the weak pages and the weak pages are refreshed at least twice during the refresh period. Therefore, refresh performance of the volatile memory devices and the memory systems may be enhanced.

### BRIEF DESCRIPTION OF THE DRAWINGS

Illustrative, non-limiting exemplary embodiments will be more clearly understood from the following detailed description taken in conjunction with the accompanying drawings.

FIG. 1 is a flow chart illustrating a method of refreshing a volatile memory device.

FIG. 2A and FIG. 2B illustrate refresh operation according to the method of refreshing a volatile memory device according to some example embodiments.

FIG. 3 is a block diagram illustrating an example of a volatile memory device according to some example embodiments.

FIG. 4 is a block diagram illustrating an example of the address storing unit in FIG. 3 according to some example embodiments.

FIG. 5 is a block diagram illustrating an example of the refresh control circuit in FIG. 3 according to some example embodiments.

FIG. 6 illustrates an example of a configuration of one of the comparing units in FIG. 5 according to some example embodiments.

FIG. 7 illustrates an example of the address changing unit in FIG. 5 according to some example embodiments.

FIG. 8 is a circuit diagram illustrating an example of the refresh pulse generator in FIG. 5 according to some example embodiments.

FIG. 9 is a circuit diagram illustrating an example of the refresh pulse generator in FIG. 5 according to some example embodiments.

FIG. 10 is a block diagram illustrating an example of the refresh control circuit in

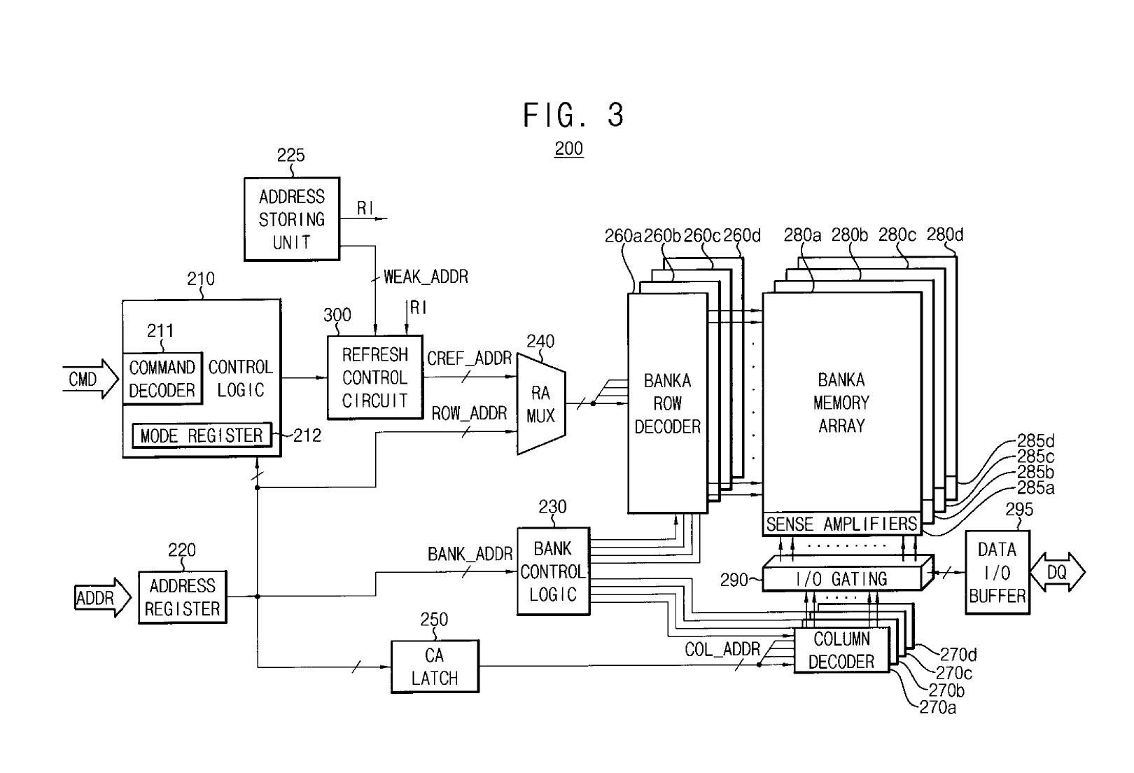

FIG. 3 according to some example embodiments.

FIG. 11 is a block diagram illustrating a memory system according to some example embodiments.

FIG. 12 is a block diagram illustrating an example of the memory controller in FIG. 11 according to some example embodiments.

FIG. 13 is a timing diagram illustrating auto refresh operation performed by the memory controller in FIG. 12.

FIG. 14 is a block diagram illustrating an example of the refresh control circuit in FIG. 3 according to some example embodiments.

FIG. 15 is a block diagram illustrating a memory system according to some example embodiments.

FIG. 16A illustrates an example of the refresh timer in FIG. 15 according to some example embodiments.

FIG. 16B illustrates an example of the refresh timer in FIG. 15 according to some example embodiments.

FIG. 17 is a block diagram illustrating a mobile system including the volatile memory device according to some exemplary embodiments.

FIG. 18 is a block diagram illustrating a computing system according to some exemplary embodiments.

### DETAILED DESCRIPTION OF THE EMBODIMENTS

Various exemplary embodiments will be described more fully hereinafter with reference to the accompanying drawings, in which some exemplary embodiments are shown. The present invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

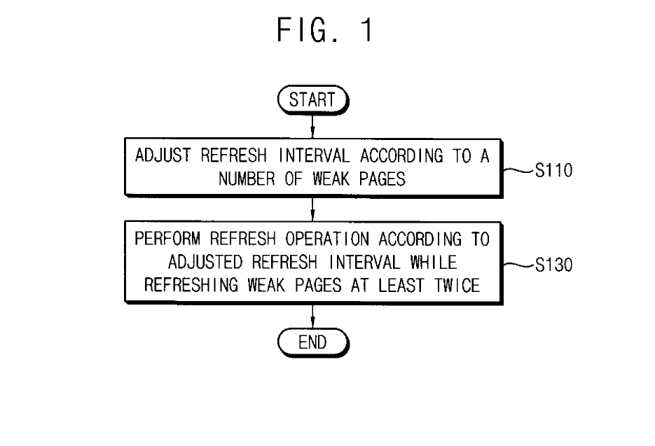

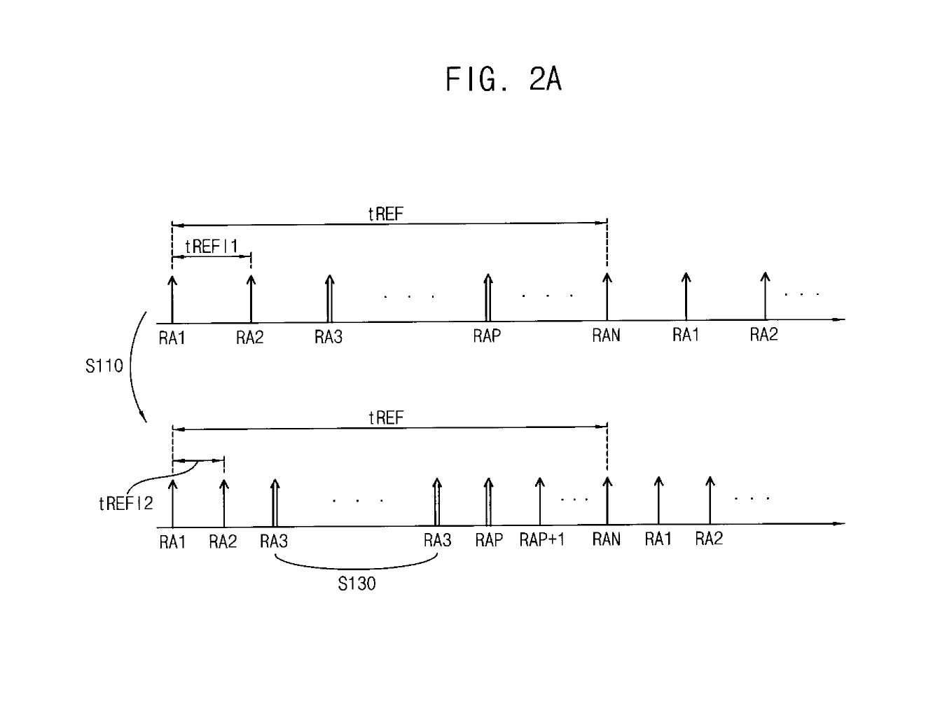

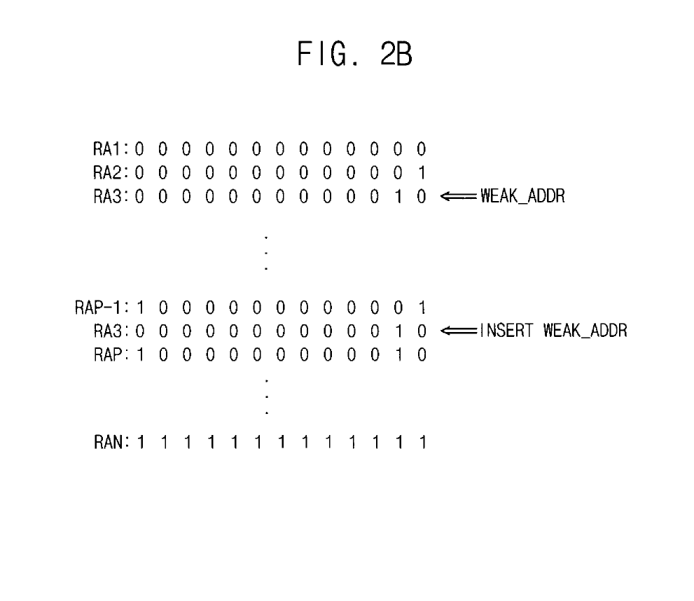

FIG. 1 is a flow chart illustrating an exemplary method of refreshing a volatile memory device and FIG. 2A and FIG. 2B illustrate an exemplary refresh operation according to the method of refreshing a volatile memory device according to some example embodiments.

Referring to FIGS. 1 through 2B, in a method of refreshing the volatile memory device, a refresh interval tREFI is adjusted according to a refresh information signal based on a number of weak pages among a plurality of pages included in a memory cell array, each weak page includes at least one weak cell whose data whose data retention time is shorter than a data retention time of normal cells (S110). In some embodiments, the refresh interval may be a refresh interval when a self refresh operation is autonomously initiated after a power-up sequence of the volatile memory device is completed. In some embodiments, the refresh interval may be a refresh interval when an auto refresh operation is performed. In the auto refresh operation, the volatile memory device automatically generates a sequence of refresh row addresses in response to a periodically applied refresh command (REF) received from a memory controller and refreshes a memory cell row corresponding to the internally generated refresh row addresses. The refresh interval indicates an interval between consecutive refresh operations, such as consecutive refresh operations on two pages (or memory cell rows). When the refresh interval is decreased during a refresh period defined in a specification, refresh cycles, and the frequency of refresh operations performed during the refresh period defined in the specification is increased. The plurality of pages may be refreshed according to the adjusted refresh interval while the weak pages are refreshed at least twice during the refresh period defined in the specification (S130).

In an embodiment, a refresh period tREF may be predetermined, such as that defined by a specification. A refresh interval during the refresh period tREF (e.g., defined in the specification) may be a first refresh interval tREFI1, as illustrated in FIG. 2A. The refresh interval may be decreased to a second refresh interval tREFI2 according to the number of weak pages during the refresh period tREF. When the refresh interval is decreased, the number of refresh cycles in the refresh period tREF may be increased, and thus, additional refresh operation may be performed on the weak pages using the increased number of refresh cycles. For example, when a refresh row address RA3 corresponds to a weak page address, a weak page having the weak page address RA3 is refreshed an additional time when a page having a refresh row address RAP is refreshed. The refresh row address RAP may differ from the weak page address RA3 by its most significant bit (MSB).

For example, assume the refresh row address RA3 is a weak page address having an address of ‘0000000000010’ and the page having the refresh row address ‘0000000000010’ is to be refreshed an additional time during the refresh period. When refresh row addresses gradually increase from ‘0000000000000’ to ‘1111111111111’ the weak page having the refresh row address ‘0000000000010’ is refreshed an additional time when the page having a refresh row address RAP of ‘1000000000010’ is to be refreshed, and then the page having the refresh row address RAP of ‘1000000000010’ is refreshed. It will be noted that the refresh row address RAP is the same as the row address of RA3 with the exception of their most significant bit (MSB). Accordingly, the weak page may be refreshed at least twice during the refresh period tREF.

FIG. 3 is a block diagram illustrating an example of a volatile memory device according to some example embodiments.

Referring to FIG. 3, a volatile memory device 200 includes a control logic circuit 210, an address register 220, a bank control logic circuit 230, a row address multiplexer 240, a column address latch 250, a row decoder, a column decoder, a memory cell array, a sense amplifier unit, an input/output gating circuit 290, a data input/output buffer 295, an address storing unit 225 and a refresh control circuit 300. In some embodiments, the volatile memory device 200 may be a dynamic random access memory (DRAM), such as a double data rate synchronous dynamic random access memory (DDR SDRAM), a low power double data rate synchronous dynamic random access memory (LPDDR SDRAM), a graphics double data rate synchronous dynamic random access memory (GDDR SDRAM), a Rambus dynamic random access memory (RDRAM), etc., or may be other volatile memory devices that require a refresh operation.

The memory cell array may include first through fourth bank arrays 280a, 280b, 280c and 280d. The row decoder may include first through fourth bank row decoders 260a, 260b, 260c and 260d respectively coupled to the first through fourth bank arrays 280a, 280b, 280c and 280d, the column decoder may include first through fourth bank column decoders 270a, 270b, 270c and 270d respectively coupled to the first through fourth bank arrays 280a, 280b, 280c and 280d, and the sense amplifier unit may include first through fourth bank sense amplifiers 285a, 285b, 385c and 385d respectively coupled to the first through fourth bank arrays 280a, 280b, 280c and 280d. The first through fourth bank arrays 280a, 280b, 280c and 280d, the first through fourth bank row decoders 260a, 260b, 260c and 260d, the first through fourth bank column decoders 270a, 270b, 270c and 270d and the first through fourth bank sense amplifiers 285a, 285b, 285c and 285d may form first through fourth banks Although the volatile memory device 200 is illustrated in FIG. 3 as including four banks, the volatile memory device 200 may include any number of banks.

The address register 220 may receive an address ADDR including a bank address BANK_ADDR, a row address ROW_ADDR and a column address COL_ADDR from a memory controller (not shown). The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic circuit 230 may generate bank control signals in response to the bank address BANK_ADDR. One of the first through fourth bank row decoders 260a, 260b, 260c and 260d corresponding to the bank address BANK_ADDR may be activated in response to the bank control signals, and one of the first through fourth bank column decoders 270a, 270b, 270c and 270d corresponding to the bank address BANK_ADDR may be activated in response to the bank control signals.

The row address multiplexer 240 may receive the row address ROW_ADDR from the address register 220, and may receive a changed refresh row address CREF_ADDR from the refresh control circuit 300. The row address multiplexer 240 may selectively output the row address ROW_ADDR or the changed refresh row address CREF_ADDR. A row address output from the row address multiplexer 240 may be applied to the first through fourth bank row decoders 260a, 260b, 260c and 260d.

The activated one of the first through fourth bank row decoders 260a, 260b, 260c and 260d may decode the row address output from the row address multiplexer 240, and may activate a word line corresponding to the row address. For example, the activated bank row decoder may apply a word line driving voltage to the word line corresponding to the row address.

The column address latch 250 may receive the column address COL_ADDR from the address register 220, and may temporarily store the received column address COL_ADDR. In some embodiments, in a burst mode, the column address latch 250 may generate column addresses that increment from the received column address COL_ADDR. The column address latch 250 may apply the temporarily stored or generated column address to the first through fourth bank column decoders 270a, 270b, 270c and 270d.

The activated one of the first through fourth bank column decoders 270a, 270b, 270c and 270d may decode the column address COL_ADDR output from the column address latch 250, and may control the input/output gating circuit 290 to output data corresponding to the column address COL_ADDR.

The input/output gating circuit 290 may include circuitry for gating input/output data. The input/output gating circuit 290 may further include an input data mask logic, read data latches for storing data output from the first through fourth bank arrays 280a, 280b, 280c and 280d, and write drivers for writing data to the first through fourth bank arrays 280a, 280b, 280c and 280d.

Data DQ to be read from one bank array of the first through fourth bank arrays 280a, 280b, 280c and 280d may be sensed by a sense amplifier coupled to the one bank array, and may be stored in the read data latches. The data DQ stored in the read data latches may be provided to the memory controller via the data input/output buffer 295. Data DQ to be written to one bank array of the first through fourth bank arrays 280a, 280b, 280c and 280d may be provide from the memory controller to the data input/output buffer 295. The data DQ provided to the data input/output buffer 295 may be written to the one array bank via the write drivers.

The control logic 210 may control operations of the memory device 200a. For example, the control logic circuit 210 may generate control signals for the memory device 200a to perform a write operation or a read operation. The control logic circuit 210 may include a command decoder 211 that decodes a command CMD received from the memory controller and a mode register 212 that sets an operation mode of the volatile memory device 200. For example, the command decoder 211 may generate the control signals corresponding to the command CMD by decoding a write enable signal (/WE), a row address strobe signal (/RAS), a column address strobe signal (/CAS), a chip select signal (/CS), etc. The command decoder 211 may further receive a clock signal (CLK) and a clock enable signal (/CKE) for operating the volatile memory device 200 in a synchronous manner. The control logic circuit 210 may control the refresh control circuit 300 to generate the changed refresh row address CREF_ADDR. That is, the control logic circuit 210 may control the refresh control circuit 300 to perform a self refresh operation on the memory cell array in a power down mode of the volatile memory device 200. In addition, the control logic circuit 210 may control the refresh control circuit 300 to perform an auto refresh operation on the memory cell array in response to an auto refresh command from a memory controller in a normal operation mode of the volatile memory device 200.

The address storing unit 225 stores the weak page addresses of the weak pages and provides the refresh control circuit 300 with the refresh information signal RI based on the number of the weak pages. Each weak page includes at least a weak cell whose data whose data retention time being shorter than data retention time of normal cells. In some embodiments, the address storing unit 225 may provide the refresh information signal RI to the memory controller. The memory controller may adjust an interval of auto refresh command provided to the volatile memory device 200 based on the refresh information signal RI.

The refresh control circuit 300 adjusts (or decreases) the refresh interval tREFI based on the weak page addresses WEAK_ADDR and the refresh information signal SI and refreshes the plurality of pages according to increased refresh cycles at the adjusted refresh interval, while the weak pages are refreshed at least twice during the refresh period.

In some embodiments, the address storing unit 225 may be included in the refresh control circuit 300. In this case, the refresh control circuit 300 may provide the refresh information signal RI to the memory controller.

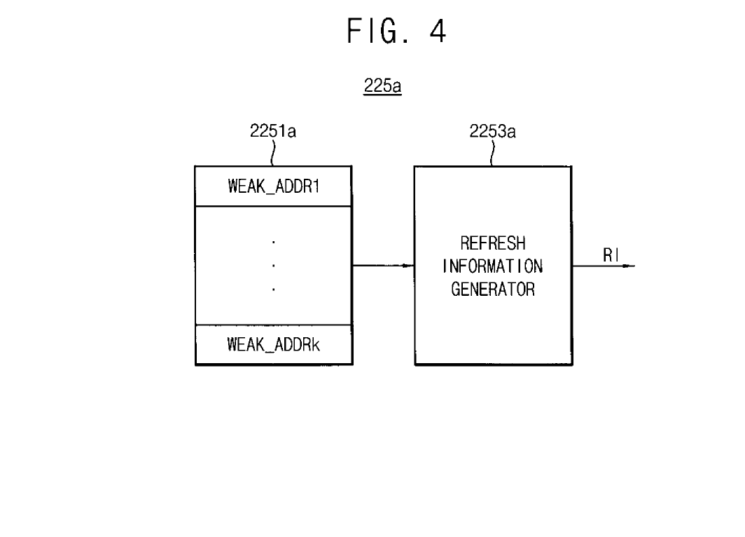

FIG. 4 is a block diagram illustrating an example of the address storing unit in FIG. 3 according to some example embodiments.

Referring to FIG. 4, an address storing unit 225a includes a weak page register 2251a and a refresh information generator 2253a. The weak page register 2251a may store the weak page addresses WEAK_ADDR1˜WEAK_ADDRk of the weak pages. Here, k is an integer is equal to or greater than two and less than a number of pages in the memory cell array. The refresh information generator 2253a generates the refresh information signal RI based on the number of the weak pages stored in the weak page register 2251a. For example, when the memory cell array includes 8K pages and the number of the weak pages is not more than 1K, the refresh information signal RI may be ‘01’. For example, when the number of the weak pages is more than 1K and not more than 2K, the refresh information signal RI may be ‘10’. For example, when the number of the weak pages is more than 2K, the refresh information signal RI may be ‘11’. In some embodiments, the weak page register 2251a may be implemented with an electrically programmable fuse memory, a laser-programmable fuse memory, an anti-fuse memory, a one-time programmable memory, a flash memory, or other types of nonvolatile memories. The refresh control circuit 300 receives the refresh information signal RI and adaptively decreases or increases the refresh interval based on bit values of the refresh information signal RI.

For example, when the memory cell array includes 8K pages and the refresh period defined in the specification is 64 ms, the unadjusted refresh interval corresponds to 7.8 us. In this case, when the number of the weak pages is 1K, an adjusted refresh interval may be 64 ms/(8K+1K)=6.9 us. That is, the refresh control circuit 300 may decrease the refresh interval from 7.8 us to 6.9 us to increase a number of refresh cycles up to 1K when the refresh information signal RI is ‘10’ and the refresh control circuit 300 refreshes the weak pages an additional time during each refresh period using the increased number of refresh cycles.

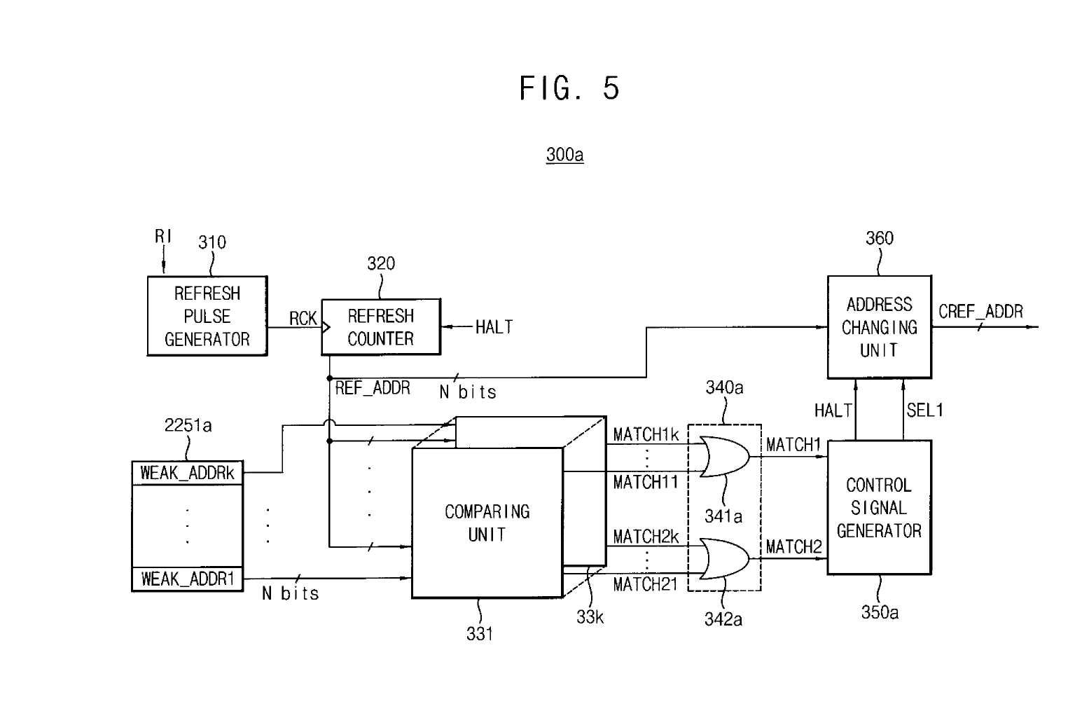

FIG. 5 is a block diagram illustrating an example of the refresh control circuit in FIG. 3 according to some example embodiments.

In FIG. 5, the weak page register 2251a is also illustrated for the sake of convenience.

Referring to FIG. 5, a refresh control circuit 300a may include a refresh pulse generator 310, a refresh counter 320, a plurality of comparing units 331˜33k, an operation unit 340a, a control signal generator 350a and an address changing unit 360.

The refresh pulse generator 310 receives the refresh information signal RI and generates a refresh pulse RCK having a period corresponding to the adjusted refresh interval. The refresh counter 320 generates a refresh row address REF_ADDR by performing counting operation at an increased refresh cycle rate in response to the refresh pulse signal RCK. The comparing units 331˜33k compare each of the weak page addresses WEAK_ADDR1˜WEAK_ADDRk and the refresh row address REF_ADDR to provide a plurality of first intermediate match signals MATCH11˜MATCH1k and compare each of abbreviated weak page addresses and an abbreviated row address to provide a plurality of second intermediate match signals MATCH21˜MATCH2k. Each of the abbreviated weak addresses may be obtained by omitting at least one MSB of each of the weak page addresses WEAK_ADDR1˜WEAK_ADDRk and the abbreviated refresh row address may be obtained by omitting at least one MSB of the refresh row address REF_ADDR.

The operation unit 342a provides a first match signal MATCH1 and a second match signal MATCH2 based on the first intermediate match signals MATCH11˜MATCH1k and the second intermediate match signals MATCH21˜MATCH2k respectively. The operation unit 340a includes OR gates 341a and 342a. The OR gates 341a performs logical OR operation on the first intermediate match signals MATCH11˜MATCH1k to provide the first match signal MATCH1 and the OR gate 342a performs logical OR operation on the second intermediate match signals MATCH21˜MATCH2k to provide the second match signal MATCH2.

Therefore, when at least one of the weak page addresses WEAK_ADDR1˜WEAK_ADDRk matches with the refresh row address REF_ADDR, the first match signal MATCH1 is a logic high level. In addition, when at least one of the abbreviated weak page addresses matches with the abbreviated refresh row address, the second match signal MATCH2 is a logic high level. That is, when at least one of the weak page addresses WEAK_ADDR1˜WEAK_ADDRk matches with the refresh row address REF_ADDR in every bit, the first and second match signals MATCH1 and MATCH2 are logic high level. When at least one of the weak page addresses WEAK_ADDR1˜WEAK_ADDRk matches with the refresh row address REF_ADDR except at least one MSB, the first match signal MATCH1 is logic low level and the second match signal MATCH2 is logic high level.

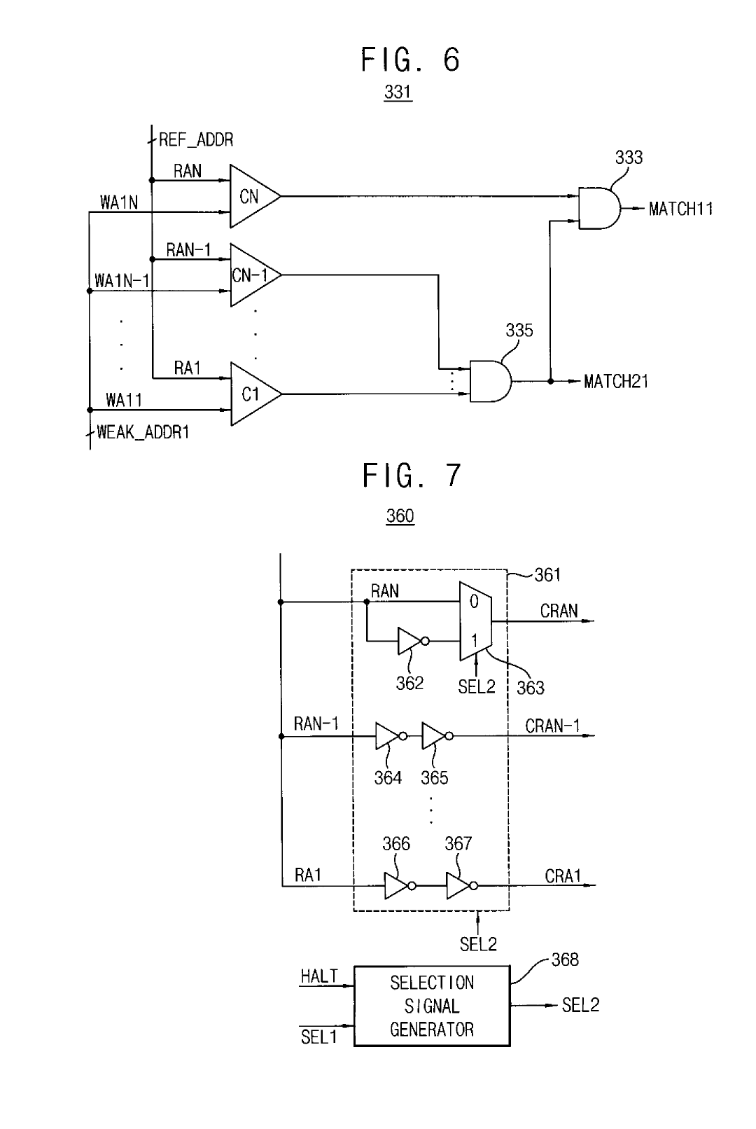

FIG. 6 illustrates an example of a configuration of one of the comparing units in FIG. 5 according to some example embodiments.

In FIG. 6, a configuration of the first comparing unit 331 of the comparing units 331˜33k in FIG. 5 is illustrated.

Referring to FIG. 6, the first comparing unit includes a plurality of comparators C1˜CN and AND gates 333 and 335. The comparators C1˜CN compares bits WA11˜WA1N of the first weak page address WEAK_ADDR1 and bits RA1˜RAN of the refresh row address REF_ADDR respectively. The AND gate 335 performs logical AND operation on outputs of the comparators C1˜CN−1 except output of the comparator CN that compares MSBs of the weak page address WEAK_ADDR1 and the refresh row address REF_ADDR to provide the second intermediate match signal MATCH21. The AND gate 333 performs logical AND operation on outputs of the AND gate 335 and the comparator CN to provide the first intermediate match signal MATCH11. Therefore, the first intermediate match signal MATCH11 is logic high level when each bit WA11˜WA1N of the first weak page address WEAK_ADDR1 matches with corresponding bit RA1˜RAN of the refresh row address REF_ADDR. In addition, the second intermediate match signal MATCH21 is logic high level when each bit WA11˜WA1N−1 of the first weak page address WEAK_ADDR1 except MSB matches with corresponding bit RA1˜RAN−1 of the refresh row address REF_ADDR except MSB. That is, when the first intermediate match signal MATCH11 is logic low level and the second intermediate match signal MATCH21 is logic high level, the refresh row address REF_ADDR is different from the first weak page address WEAK_ADDR1 in the MSB.

Referring back to FIG. 5, the control signal generator 350a decodes the first and second match signals MATCH1 and MATCH2 to generate the halt signal HALT for halting operation of the refresh counter 320 during the refresh interval and the first selection signal SEL1 for determining whether the at least one MSB of the refresh row address REF_ADDR. The control signal generator 350a enables the halt signal HALT to logic high level and enables the first selection signal SEL1 to logic high level when the first match signal MATCH1 is logic low level and the second match signal MATCH2 is logic high level. The control signal generator 350a maintains the halt signal HALT and the first selection signal SEL1 at logic low level in other cases.

FIG. 7 illustrates an example of the address changing unit in FIG. 5 according to some example embodiments.

Referring to FIG. 7, the address changing unit 360 includes a refresh row address output unit 361 and a selection signal generator 368. The selection signal generator 368 receives the halt signal HALT and the first selection signal SEL1 and selectively inverts the first selection signal SEL1 to provide a second selection signal SEL2 based on transition of the halt signal HALT. The selection signal generator 368 inverts the first selection signal SEL1 to provide the second selection signal SEL2 in response to high to low transition of the halt signal HALT and the selection signal generator 368 maintains the level of the second selection signal SEL2 to provide the second selection signal SEL2 to the refresh row address output unit 361 and allow its selection of the inverted MSB of the refresh row address REF_ADDR by its multiplexer 363 as now described.

The refresh row address output unit 361 includes an inverter 362 that inverts the MSB of the refresh row address REF_ADDR, a multiplexer 363 and a plurality of inverters 364˜367. The multiplexer 363 selects one of the MSB RN of the refresh row address REF_ADDR and an output of the inverter 362 to provide MSB CRAN of a changed refresh row address CREF_ADDR. The inverters 364˜367 outputs first through N−1-th bits CRA1 and CRAN−1 of the changed refresh row address CREF_ADDR by delaying the first through N−1-th bits RA1 and RAN−1 of the refresh row address REF_ADDR.

Therefore, when the refresh row address REF_ADDR matches with at least one of the weak page addresses WEAK_ADDR1˜WEAK_ADDRk except at least one MSB, the first match signal MATCH1 is low level and the second match signal MATCH2 is high level, and thus, the halt signal HALT is made a high level and the first selection signal SEL1 is made a high level. Accordingly, the second selection signal SEL2 is a low level causing multiplexer 363 to select the inverted MSB of the refresh row address REF_ADDR (here, the inverted logic value of RAN). The refresh row address output unit 361 thus outputs the changed refresh row address CREF_ADDR with the inverted MSB RAN. When it is not the case that the refresh row address REF_ADDR matches with at least one of the weak page addresses WEAK_ADDR1˜WEAK_ADDRk except at least one MSB, the second selection signal will not be generated to cause selection of the inverted MSB, but will cause selection of MSB to be output as CRAN. As will be apparent, in this instance changed refresh row address CREF_ADDR will be the same as the previously input refresh row address REF_ADDR (i.e., unchanged).

When the halt signal HALT is maintained at high level during the refresh interval, the refresh counter 320 halts its counting operating during this refresh interval. When the halt signal HALT transitions to a low level, the refresh counter 320 starts the counting operation again. The refresh counter 320 resumes the counting operation starting at the refresh row address of the refresh counter when the refresh counter 320 was halted in its the counting operation. The refresh counter outputs the refresh row address REF_ADDR whose MSB is different from the weak page address. In this case, the first match signal MATCH1 is low level and the second match signal MATCH2 is high level. However, the halt signal HALT transitions from high level to low level, the selection signal generator 368 inverts the first selection signal SEL1 to provide the second selection signal SEL2. Since the second selection signal SEL2 is low level even when the first selection signal SEL1 is high level, the refresh row address output unit 361 maintains the MSB RAN of the refresh row address REF_ADDR to output the MSB CRAN of the changed refresh row address CREF_ADDR. Therefore, the refresh operation in FIG. 2B is performed.

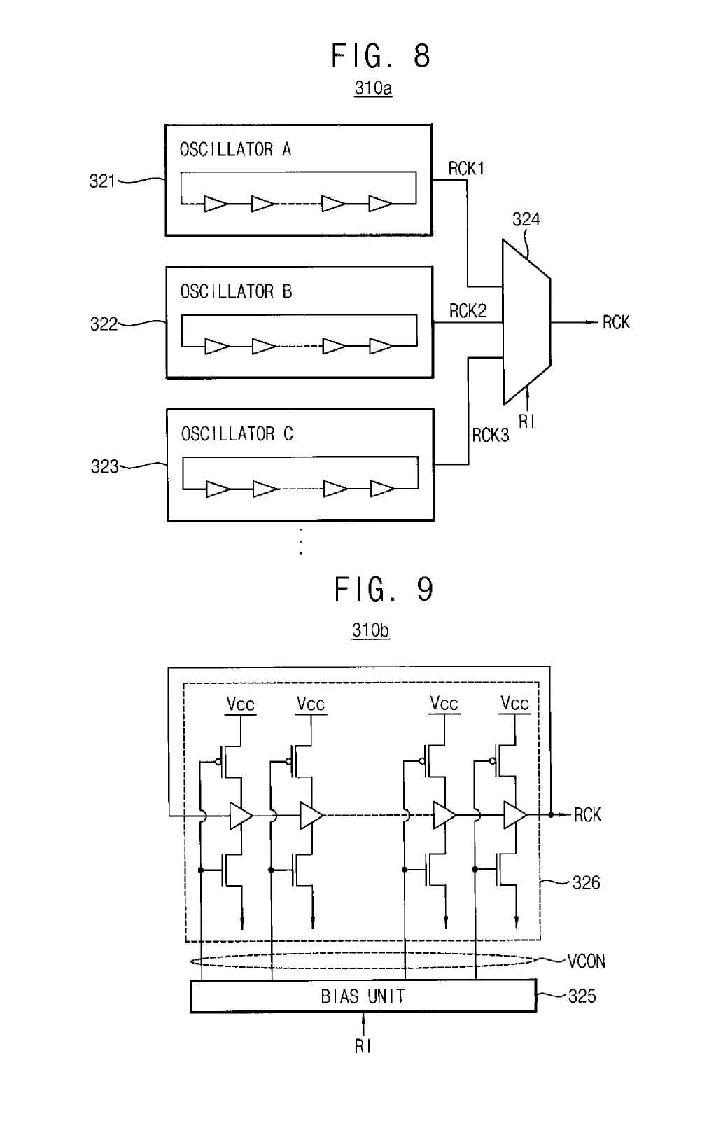

FIG. 8 is a circuit diagram illustrating an example of the refresh pulse generator in FIG. 5 according to some example embodiments.

Referring to FIG. 8, a refresh pulse generator 310a includes a plurality of oscillator 311, 312 and 313 and a multiplexer 314. The oscillators 311, 312, and 313 generate refresh pulse signals RCK1, RCK2 and RCK3 having different period. The multiplexer 314 selects one of the refresh pulse signals RCK1, RCK2 and RCK3 to provide the refresh pulse signal RCK in response to the refresh information signal RI. For example, when the multiplexer 324 selects the refresh pulse signal RCK2, the refresh counter 320 may perform the counting operation with 9K refresh cycles during the refresh period.

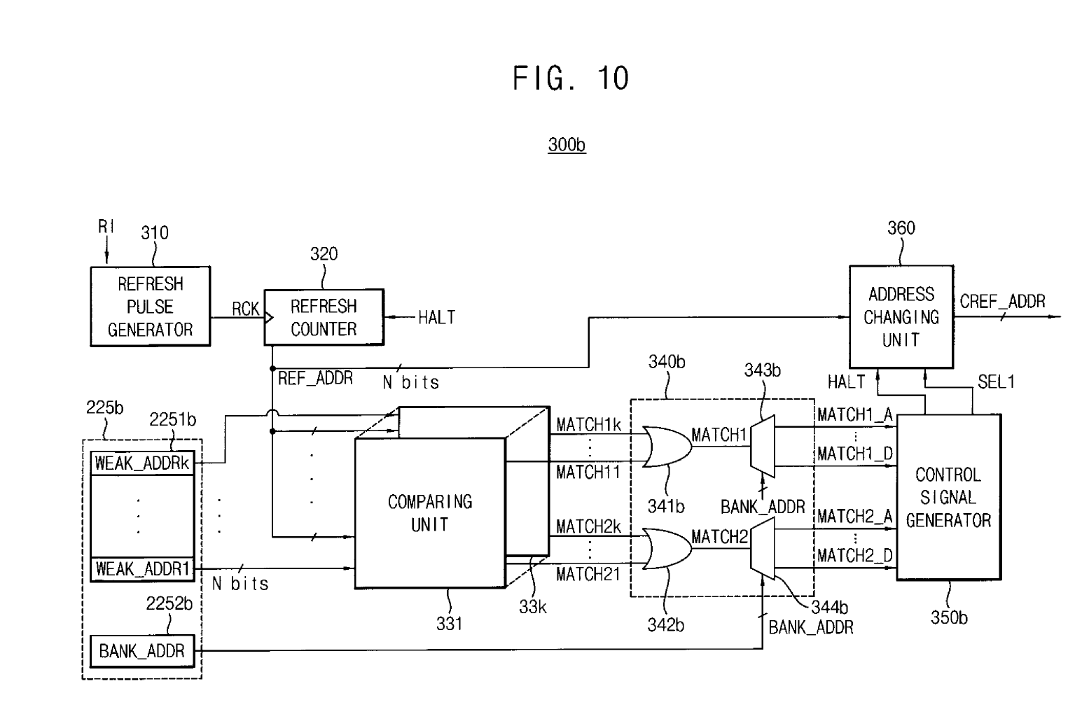

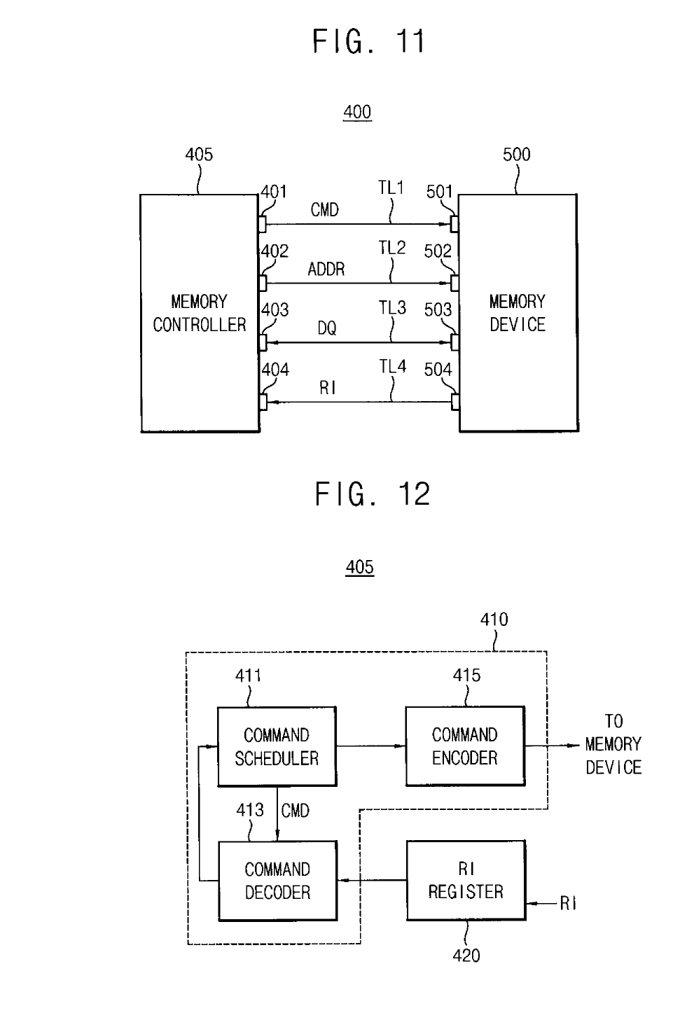

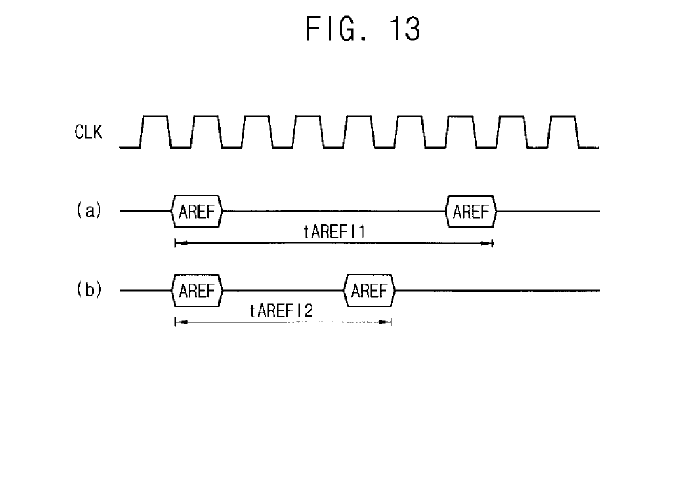

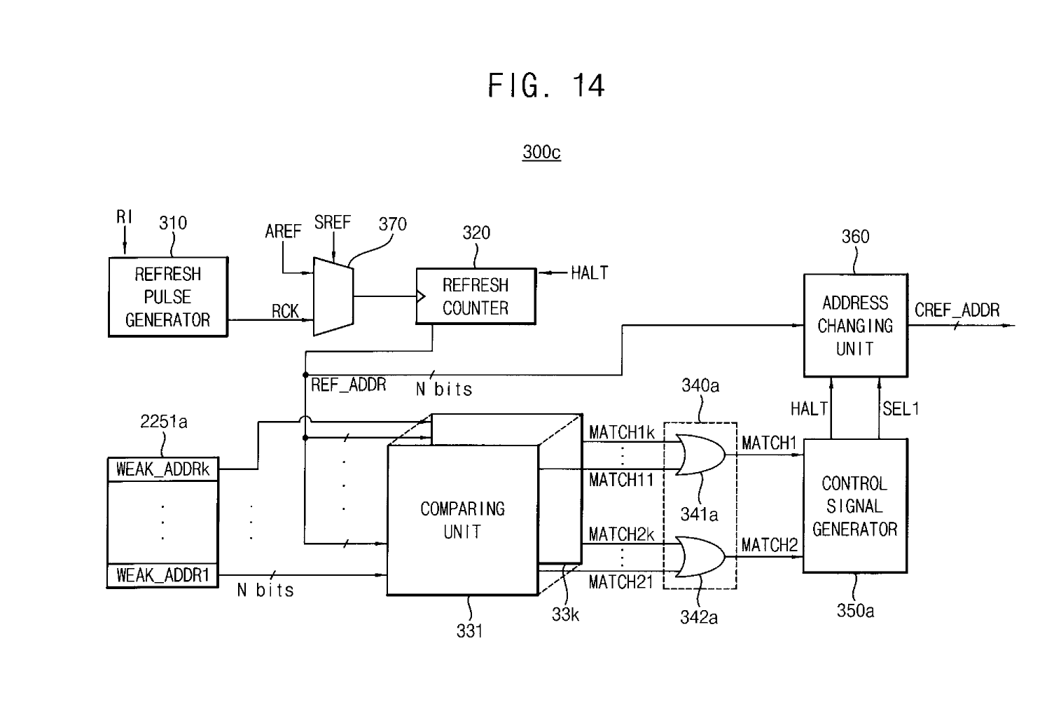

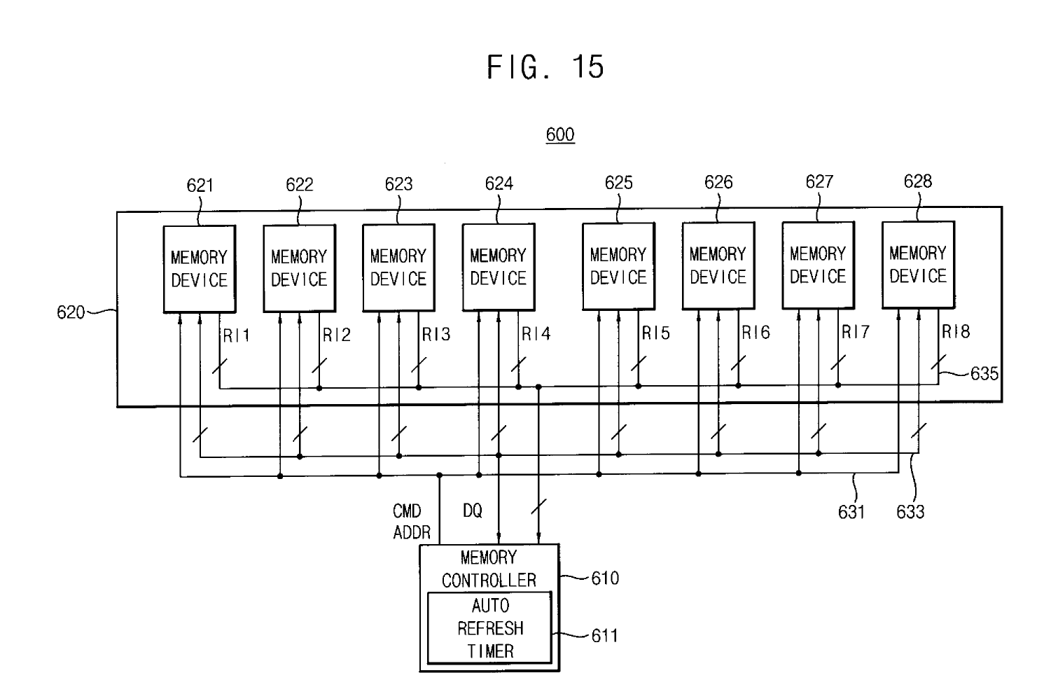

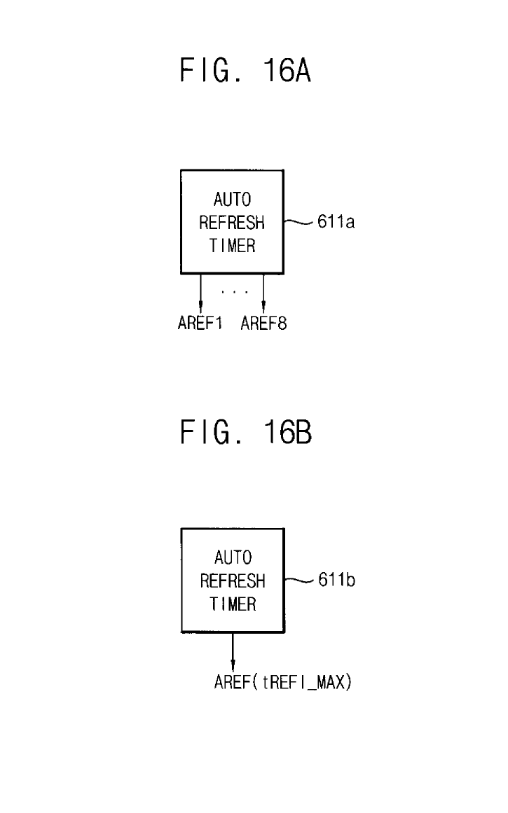

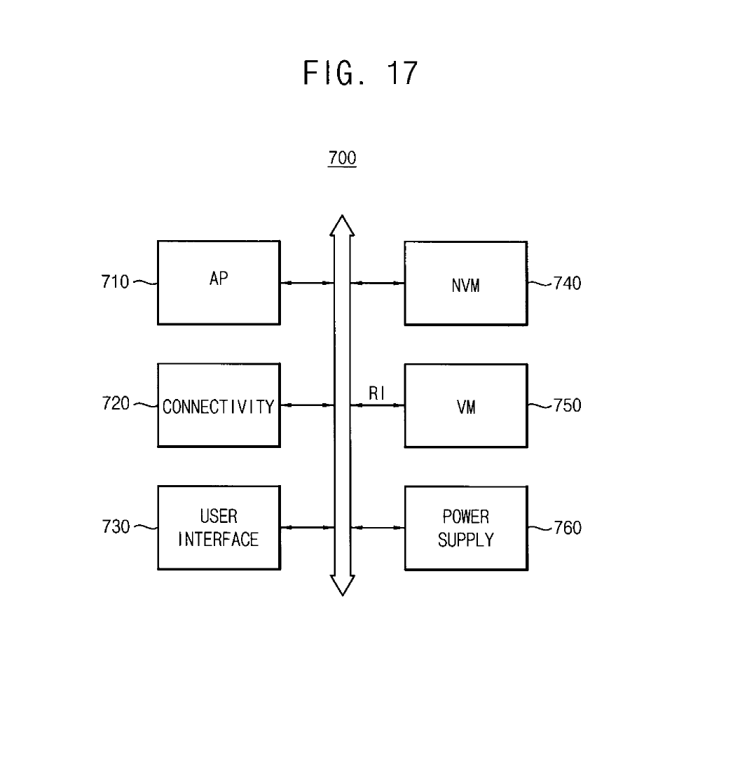

FIG. 9 is a circuit diagram illustrating an example of the refresh pulse generator in FIG. 5 according to some example embodiments.

Referring to FIG. 9, a refresh pulse generator 310b includes bias unit 325 and an oscillator 326. The bias unit 325 generates a control voltage VCON in response to the refresh information signal RI. The oscillator 325 generates the refresh pulse signal RCK having a variable period, according to the control voltage VCON.

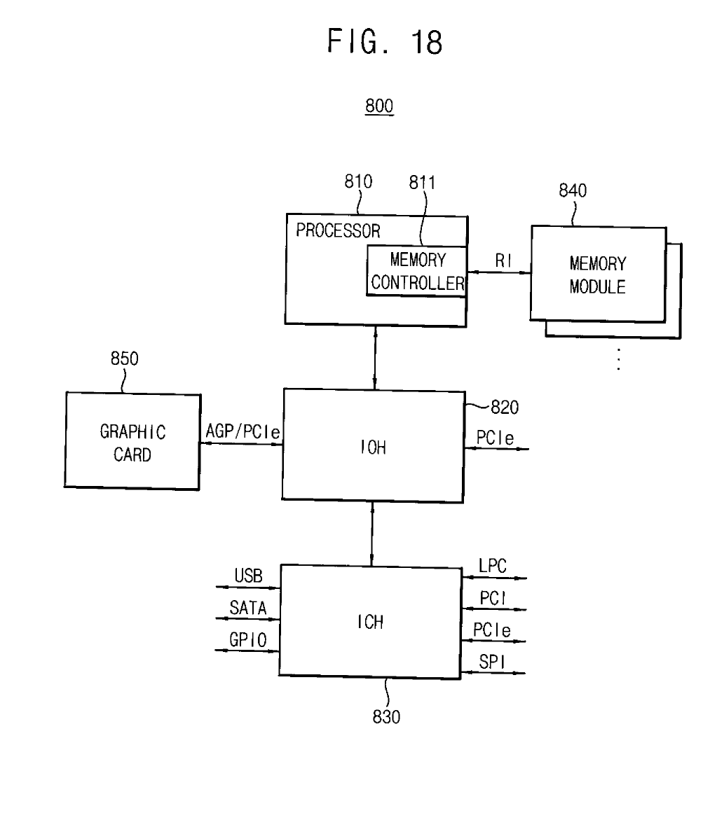

FIG. 10 is a block diagram illustrating an example of the refresh control circuit in FIG. 3 according to some example embodiments.

A refresh control circuit 300b of FIG. 10 differs from the refresh control circuit 300a of FIG. 5 in an operation unit 340b and a control signal generator 350b. In addition, the refresh control circuit 300b of FIG. 10 may be employed when the address storing unit 225 in FIG. 3 employs an address storing unit 225b.

Referring to FIG. 10, the address storing unit 225b includes a weak page register 2251b for storing the weak page addresses WEAK_ADDR1˜WEAK_ADDRk and a bank address register 2252b that stores bank address information BANK_ADDR. The bank information BANK_ADDR may designate a bank including the weak pages corresponding to the weak page addresses WEAK_ADDR1˜WEAK_ADDRk. The comparing units 331˜33k compares each of the weak page addresses WEAK_ADDR1˜WEAK_ADDRk and the refresh row address REF_ADDR to provide the first intermediate match signals MATCH11˜MATCH1k and compares each of abbreviated weak page addresses and an abbreviated row address to provide the second intermediate match signals MATCH21˜MATCH2k. The operation unit 340b includes OR gates 341b and 342b and demultiplexers 343b and 344b. The OR gates 341b performs logical OR operation on the first intermediate match signals MATCH11˜MATCH1k to provide the first match signal MATCH1 and the OR gate 342b performs logical OR operation on the second intermediate match signals MATCH21˜MATCH2k to provide the second match signal MATCH2. The demultiplexer 343b may output the first match signal MATCH1 as first bank match signals MATCH1_A˜MATCH1_D corresponding to the bank address BANK_ADDR, and the demultiplexer 344b may output the second match signal MATCH2 as second bank match signals MATCH2_A˜MATCH2_D corresponding to the bank address BANK_ADDR.

The control signal generator 350b decodes the first and second match signals MATCH1 and MATCH2 to generate the halt signal HALT for halting operation of the refresh counter 320 during the refresh interval and to generate the first selection signal SEL1 for determining at least one MSB of the changed refresh row address CREF_ADDR. The control signal generator 350b enables the halt signal HALT to logic high level and enables the first selection signal SEL1 to logic high level when the first match signal MATCH1 is logic low level and the second match signal MATCH2 is logic high level. The control signal generator 350b maintains the halt signal HALT and the first selection signal SEL1 at a logic low level in other cases. The address changing unit 360 inverts the MSB of the refresh row address REF_ADDR to provide the changed refresh row address CREF_ADDR with an inverted MSB in response to the halt signal HALT and the first selection signal SEL1 in a bank where the refresh row address REF_ADDR is to be changed. The address changing unit 360 may thus invert the MSB of the refresh row address REF_ADDR and may perform additional refresh operation in a bank corresponding to the bank address BANK_ADDR.

FIG. 11 is a block diagram illustrating a memory system according to some example embodiments.

Referring to FIG. 11, a memory system 400 includes a memory controller 405 and a volatile memory device 500. Each of the memory controller 405 and the volatile memory device 500 may be formed as a separate semiconductor chip or as a separate group of chips. The memory controller 405 and the volatile memory device 500 may be connected to each other through corresponding command pins 401 and 501, corresponding address pins 402 and 502, corresponding data pins 403 and 503 and corresponding separate pins 404 and 504. The command pins 401 and 501 transmit a command signal CMD through a command transmission line TL1, the address pins 402 and 502 transmit an address signal ADDR through an address transmission line TL2, the data pins 403 and 503 exchange data DQ through a data transmission line TL3 and the separate pins 404 and 504 transmit refresh information signal RI through a separate transmission line TL4. For ease of description, for each of the memory controller 405 and volatile memory device 500, only a single pin and associated transmission line is shown and described for each of the command signal CMD, address signal ADDR, data signal DQ and data mask signal DM/Refresh Request Information RI. However, multiple pins (and corresponding transmission lines) may be used to transmit and receive these signals. Further, other pin/transmission line arrangements may be utilized, such as pins/transmission lines that each transmit and/or receive two or more of address, data and command information (e.g., command/address pins (CA) for the communication of command and address information over shared transmission lines). In addition, the use of the word pins is used in the generic sense and should not be considered limited to prong type connectors, but includes any communication terminals of a semiconductor device, such as solder bumps or solder balls in a ball grid array package for electrical communication of signals, and optical terminals for transmitting and receiving optical signals, etc.

FIG. 12 is a block diagram illustrating an example of the memory controller in FIG. 11 according to some example embodiments.

Referring to FIG. 12, the memory controller 405 includes a register 420 for storing the refresh information signal RI and a command generation block 410. The command generation block 410 includes a command scheduler 411, a memory command decoder 413, and a command encoder 415. The command scheduler 411 generates auto refresh command CMD according to a predetermined work request and sends the generated auto refresh command CMD to the memory command decoder 413. When the memory command decoder 413 decodes the received command and identifies the command as the auto refresh command CMD, the memory command decoder 413 receives the refresh information signal RI from the register The memory command decoder 413 sets an auto refresh interval with respect to the volatile memory device 500 according to the received refresh information signal RI, and informs the command scheduler 411 of an effective time of the auto refresh command according to the set auto refresh interval. Then, the command scheduler 411 generates the auto refresh command at the corresponding time. The command encoder 415 encodes the generated auto refresh command to be transmitted to the volatile memory device 500. The volatile memory device 500 performs an auto refresh operation according to the intervals of the auto refresh command with the weak pages being refreshed at least twice during the refresh period.

FIG. 13 is a timing diagram illustrating auto refresh operation performed by the memory controller in FIG. 12.

In FIG. 13, a reference numeral (a) indicates that the memory controller 405 does not adjust the interval of the auto refresh command and a reference numeral (b) indicates that the memory controller 405 adjusts the interval of the auto refresh command according to the refresh information signal RI from the volatile memory device 500.

Referring to FIG. 13, in case of (a), the interval of the auto refresh command corresponds to tAREFI1 while in case of (b), the interval of the auto refresh command is decreased to tAREFI2 according to the number of weak pages. When the interval of the auto refresh command is decreased to tAREFI2, the number of refresh cycles are increased during the refresh period (e.g., a refresh period defined by a specification), and thus the weak pages are refreshed at least twice using the increased number of refresh cycles.

FIG. 14 is a block diagram illustrating an example of the refresh control circuit in FIG. 3 according to some example embodiments.

A refresh control circuit 300c of FIG. 14 differs from the refresh control circuit 300a of FIG. 5 in that the refresh control circuit 300c further include a multiplexer 370.

The multiplexer 310 selects one of the refresh pulse signal RCK from the refresh pulse generator 310 and an auto refresh signal AREF decoded in the command decoder 211 to provide the selected one to the refresh counter 320. That is, the multiplexer 370 selects the auto refresh signal AREF to be provided to the refresh counter 320 in a normal access mode and selects the refresh pulse signal RCK to be provided to the refresh counter 320 in a power down mode.

The refresh control circuit 300c ma sequentially generate the refresh row address REF_ADDR in response to the auto refresh signal AREF that has an interval corresponding to the interval of the auto refresh command from the memory controller 405 in the normal access mode and inverts the MSB of the refresh row address REF_ADDR to provide the changed refresh row address CREF_ADDR when the refresh row address REF_ADDR matches with at least one of the weak page addresses WEAK_ADDR1˜WEAK_ADDRk except the MSB (or except a certain number of MSBs). In addition, the refresh control circuit 300c may sequentially generate the refresh row address REF_ADDR in response to the adjusted refresh pulse signal RCK according to the refresh information signal RI in the power down mode and inverts the MSB of the refresh row address REF_ADDR to provide the changed refresh row address CREF_ADDR when the refresh row address REF_ADDR matches with at least one of the weak page addresses WEAK_ADDR1˜WEAK_ADDRk except the MSB (or except a certain number of MSBs). Therefore, the refresh control circuit 300c generates the refresh row address REF_ADDR according to the adjusted refresh intervals based on the number of the weak pages and performs additional refresh operation on the weak pages in the normal access mode or the power down mode.

FIG. 15 is a block diagram illustrating a memory system according to some example embodiments.

Referring to FIG. 15, a memory system 600 includes a memory controller 610 and a memory module 620. The memory module 620 includes a plurality of volatile memory devices 621˜628. Each of the memory devices 621˜628 exchanges data DQ with the memory controller 610 through a data transmission line 633. The memory controller 610 transmits command CMD and address ADDR signals to the each of the memory devices 621˜628 through a command/address transmission line 631.

Each of the volatile memory devices 621˜628 transmits each of refresh information signals RI1˜RI8 to the memory controller 610 through a dedicated transmission line 635. Each of refresh information signals RI1˜RI8 may include identification information for identifying each of the volatile memory devices 621˜628. The memory controller 610 may include an auto refresh timer 611. The auto refresh timer 611 decodes each of the refresh information signals RI1˜RI8 to apply the auto refresh command to each of the volatile memory devices 621˜628 at an individual interval according to decoded refresh information signals RI1˜RI8 of the corresponding volatile memory device.

In some embodiments, the auto refresh timer 611 decodes each of the refresh information signals RI1˜RI8 to apply the auto refresh command to each of the volatile memory devices 621˜628 at same interval according to one of the refresh information signals RI1˜RI8 of a volatile memory device having maximum weak pages.

In some embodiments, when the volatile memory devices 621˜628 perform self refresh operation in the power down mode, each of the memory devices 621˜628 performs self refresh operation at individual refresh cycles according to respective numbers of the weak pages of the respective volatile memory devices. In this case, each weak pages in each of the volatile memory devices 621˜628 are refreshed at least twice during the refresh period independently.

FIG. 16A illustrates an example of the refresh timer in FIG. 15 according to some example embodiments.

Referring to FIG. 16A, a refresh timer 611a may decode each of the refresh information signals RI1˜RI8 to apply the auto refresh signals AREF1˜AREF8 respectively to each of the volatile memory devices 621˜628 at an individual interval according to decoded refresh information signals RI1˜RI8 of the corresponding volatile memory device. Each of the volatile memory devices 621˜628 performs auto refresh operation according to respective auto refresh signals AREF1˜AREF8, and refreshes the respective weak pages at least twice during the refresh period.

FIG. 16B illustrates an example of the refresh timer in FIG. 15 according to some example embodiments.

Referring to FIG. 16B, a refresh timer 611b may decode each of the refresh information signals RI1˜RI8 to apply auto refresh signal AREF to each of the volatile memory devices 621˜628 at same interval. The auto refresh signal AREF may be generated based on the refresh information signal of volatile memory device having the maximum number of weak pages. The auto refresh signal AREF may have shortest refresh interval tREFI_MAX. For example, when the refresh cycles per refresh period required for a first volatile memory device is 10K, a second volatile memory device requiring 9K refresh cycles per refresh period may skip one refresh operation of every 10 refresh operations of the first volatile memory device, and a third volatile memory device requiring 8K refresh cycles per refresh period may skip two refresh operations of every 10 refresh operations of the first volatile memory device.

FIG. 17 is a block diagram illustrating a mobile system according to some exemplary embodiments.

Referring to FIG. 17, a mobile system 700 includes an application processor 710, a connectivity unit 720, a volatile memory device 750, a nonvolatile memory device 740, a user interface 730 and a power supply 760. In some embodiments, the mobile system 700 may be a mobile phone, a smart phone, a personal digital assistant (PDA), a portable multimedia player (PMP), a digital camera, a music player, a portable game console, a navigation system, etc. The volatile memory device 750 may be a volatile memory device as described according to other embodiments described herein. The application processor 710 may include a memory controller according to other embodiments described herein.

The application processor 710 may execute applications, such as a web browser, a game application, a video player, etc. In some embodiments, the application processor 710 may include a single core or multiple cores. For example, the application processor 710 may be a multi-core processor, such as a dual-core processor, a quad-core processor, a hexa-core processor, etc. The application processor 710 may include an internal or external cache memory.

The connectivity unit 720 may perform wired or wireless communication with an external device. For example, the connectivity unit 720 may perform Ethernet communication, near field communication (NFC), radio frequency identification (RFID) communication, mobile telecommunication, memory card communication, universal serial bus (USB) communication, etc. In some embodiments, connectivity unit 720 may include a baseband chipset that supports communications, such as global system for mobile communications (GSM), general packet radio service (GPRS), wideband code division multiple access (WCDMA), high speed downlink/uplink packet access (HSxPA), etc.

The volatile memory device 750 may store data processed by the application processor 710, or may operate as a working memory. For example, the volatile memory device 750 may be a dynamic random access memory, such as DDR SDRAM, LPDDR SDRAM, GDDR SDRAM, RDRAM, etc., or may be any volatile memory device that requires a refresh operation. The volatile memory device 750 may provide the refresh information signal RI according to the number of the weak pages to the application processor 710, and the application processor 710 generates the auto refresh command according to decreased refresh interval such that the weak pages are refreshed at least twice during the refresh period. In addition, the volatile memory device 750 generates the refresh row address according to the adjusted refresh intervals based on the number of the weak pages and performs additional refresh operation on the weak pages in the normal access mode or the power down mode.

The nonvolatile memory device 740 may store a boot image for booting the mobile system 700. For example, the nonvolatile memory device 740 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The user interface 730 may include at least one input device, such as a keypad, a touch screen, etc., and at least one output device, such as a speaker, a display device, etc. The power supply 760 may supply a power supply voltage to the mobile system 1100. In some embodiments, the mobile system 700 may further include a camera image processor (CIS), and/or a storage device, such as a memory card, a solid state drive (SSD), a hard disk drive (HDD), a CD-ROM, etc.

In some embodiments, the mobile system 700 and/or components of the mobile system 1100 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

FIG. 18 is a block diagram illustrating a computing system according to some exemplary embodiments.

Referring to FIG. 18, a computing system 800 includes a processor 810, an input/output hub (IOH) 820, an input/output controller hub (ICH) 830, at least one memory module 840 and a graphics card 850. In some embodiments, the computing system 800 may be a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, a navigation system, etc.

The processor 810 may perform various computing functions, such as executing specific software for performing specific calculations or tasks. For example, the processor 810 may be a microprocessor, a central process unit (CPU), a digital signal processor, or the like. In some embodiments, the processor 810 may include a single core or multiple cores. For example, the processor 810 may be a multi-core processor, such as a dual-core processor, a quad-core processor, a hexa-core processor, etc. Although FIG. 18 illustrates the computing system 800 including one processor 810, in some embodiments, the computing system 800 may include a plurality of processors. The processor 810 may include an internal or external cache memory.

The processor 810 may include a memory controller 811 for controlling operations of the memory module 840. The memory controller 811 included in the processor 810 may be referred to as an integrated memory controller (IMC). The memory controller 811 may comprise a memory controller according to other embodiments described herein. A memory interface between the memory controller 811 and the memory module 840 may be implemented with a single channel including a plurality of signal lines, or may be implemented with multiple channels, to each of which at least one memory module 840 may be coupled. In some embodiments, the memory controller 811 may be located inside the input/output hub 820, which may be referred to as memory controller hub (MCH).

The memory module 840 may include a plurality of volatile memory devices that store data provided from the memory controller 811. The volatile memory devices may be a volatile memory device as described according to other embodiments described herein. The volatile memory devices provide the refresh information signal RI according to the number of the weak pages to the memory controller 811, and the memory controller 811 generates the auto refresh command according to decreased refresh interval such that the weak pages are refreshed at least twice during the refresh period. In addition, each of the volatile memory devices may generate the refresh row address according to the adjusted refresh intervals based on the number of the weak pages and performs additional refresh operation on the weak pages in the normal access mode or the power down mode.

The input/output hub 820 may manage data transfer between processor 810 and devices, such as the graphics card 850. The input/output hub 820 may be coupled to the processor 810 via various interfaces. For example, the interface between the processor 810 and the input/output hub 820 may be a front side bus (FSB), a system bus, a HyperTransport, a lightning data transport (LDT), a QuickPath interconnect (QPI), a common system interface (CSI), etc. Although FIG. 18 illustrates the computing system 800 including one input/output hub 820, in some embodiments, the computing system 800 may include a plurality of input/output hubs. The input/output hub 820 may provide various interfaces with the devices. For example, the input/output hub 820 may provide an accelerated graphics port (AGP) interface, a peripheral component interface-express (PCIe), a communications streaming architecture (CSA) interface, etc.

The graphics card 850 may be coupled to the input/output hub 820 via AGP or PCIe. The graphics card 850 may control a display device (not shown) for displaying an image. The graphics card 850 may include an internal processor for processing image data and an internal memory device. In some embodiments, the input/output hub 820 may include an internal graphics device along with or instead of the graphics card 850 outside the graphics card 850. The graphics device included in the input/output hub 820 may be referred to as integrated graphics. Further, the input/output hub 820 including the internal memory controller and the internal graphics device may be referred to as a graphics and memory controller hub (GMCH).

The input/output controller hub 830 may perform data buffering and interface arbitration to efficiently operate various system interfaces. The input/output controller hub 830 may be coupled to the input/output hub 820 via an internal bus, such as a direct media interface (DMI), a hub interface, an enterprise Southbridge interface (ESI), PCIe, etc. The input/output controller hub 830 may provide various interfaces with peripheral devices. For example, the input/output controller hub 830 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some embodiments, the processor 810, the input/output hub 820 and the input/output controller hub 830 may be implemented as separate chipsets or separate integrated circuits. In other embodiments, at least two of the processor 810, the input/output hub 820 and the input/output controller hub 830 may be implemented as a single chipset.

As mentioned above, the interval of the auto refresh command or the self refresh interval may be adaptively adjusted based on the refresh information signal according to the number of the weak pages and the weak pages are refreshed at least twice during the refresh period. Therefore, refresh performance of the volatile memory devices and the memory systems may be enhanced.

The present inventive concept may be applied to any volatile memory device that requires a refresh operation and to a system including the volatile memory device. The present inventive concept may be applied to systems such as be a mobile phone, a smart phone, a personal digital assistant (PDA), a portable multimedia player (PMP), a digital camera, a music player, a portable game console, a navigation system, etc. The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims.

What is claimed is:

1. A volatile memory device, comprising:
a memory cell array including a plurality of pages; and
a refresh control circuit configured to refresh the plurality of pages every refresh period by performing, during each refresh period, refresh operations at regular refresh intervals to corresponding selected ones of the plurality of pages, configured to adjust the refresh interval according to a number of the plurality of pages identified as weak pages including at least a weak cell whose data retention time being shorter than a data retention time of normal cells, and configured to refresh the pages identified as weak pages at least twice during each refresh period.

2. The volatile memory device of claim 1,
wherein a first page of the pages identified as weak pages has a first address,
wherein the refresh control circuit is configured to refresh the first page in response to the refresh control circuit generating a refresh address of one of the plurality of pages, and
wherein the first address is the same as the refresh address except that the first address differs from the refresh address by at least one most significant bit (MSB).

3. The volatile memory device of claim 2, wherein the refresh control circuit is configured to selectively invert the at least one MSB of a refresh address to provide a changed refresh address based on a first comparison of the first address and the refresh address and a second comparison of an abbreviated first address and an abbreviated refresh address, the abbreviated first address and the abbreviated refresh address respectively being the first address and refresh address without the corresponding at least one MSB.

4. The volatile memory device of claim 1, wherein the refresh control circuit comprises:
a refresh pulse generator configured to generate a refresh pulse signal having a period corresponding to the refresh interval;
a refresh counter configured to generate a refresh address by performing a counting operation in response to the refresh pulse signal;
a plurality of comparing units each configured to compare a corresponding one of weak page addresses of the pages identified as weak pages and the refresh address to provide a corresponding first intermediate match signal and configured to compare a corresponding one of abbreviated weak page addresses and an abbreviated refresh address to provide a corresponding second intermediate match signal, each of the abbreviated weak page addresses being the corresponding weak page address without its at least one MSB, the abbreviated refresh address being the refresh address without its at least one MSB;
an operation unit configured to provide a first match signal based on the first intermediate match signals and a second match signal based on the second intermediate match signals;
a control signal generator configured to generate a halt signal that halts an operation of the refresh counter during the refresh period, based on the first match signal and the second match signal; and
an address changing unit configured to selectively invert the at least one MSB of the refresh address to provide a changed refresh address.

5. The volatile memory device of claim 4, wherein the operation unit comprises a first OR circuit to perform a logical OR operation on the first intermediate match signals to provide the first match signal and a second OR circuit to perform a logical OR operation on the second intermediate match signals to provide the second match signal.

6. The volatile memory device of claim 4, wherein the operation unit provides the first match signal as a first match detected logic level when the at least one of the weak page addresses match with the refresh address and provides the second match signal with second match detected logic level when at least one of the abbreviated weak page addresses matches with the abbreviated refresh address.

7. The volatile memory device of claim 6, wherein the control signal generator is configured to enable the halt signal and to invert the at least one MSB of the refresh address to provide the changed refresh address when the first match signal is not the first match detected logic level and the second match signal is the second match detected logic.

8. The volatile memory device of claim 7, wherein the refresh counter is configured to halt the counting operation when the halt signal is enabled and when the halt signal is disabled, the refresh counter is configured to restart the counting operation at a refresh address of the refresh counter when the halt signal was enabled.

9. The volatile memory device of claim 1, further comprising:
a weak page register configured to store weak page addresses of the pages identified as weak pages; and
a refresh information generator configured to generate a refresh information signal based on the number of the weak pages stored in the weak page register,
wherein the refresh control circuit is configured to adjust the refresh interval according to the refresh information signal.

10. The volatile memory device of claim 9, further comprising:
a bank address register configured to store information on a plurality of bank addresses of banks constituting the memory cell array,
wherein the refresh control circuit is configured to refresh the pages identified as weak pages at least twice during the refresh period in a bank corresponding to one of the bank addresses stored in the bank address register.

11. A memory system comprising:
a first volatile memory device; and
a memory controller configured to control the first volatile memory device, wherein the first volatile memory device is configured to provide the memory controller with refresh information signal corresponding to a number of identified weak pages that include at least a weak cell whose data retention time is shorter than a data retention time of normal cells,
wherein the memory controller is configured to provide an auto refresh command to the first volatile memory device at regular refresh intervals over a refresh period and is configured to adjust the refresh interval according to the refresh information signal, and
wherein the first volatile memory device is configured to refresh a plurality of pages in response to auto refresh commands received during the refresh period while refreshing the identified weak pages of the plurality of pages at least twice during the refresh period.

12. The memory system of claim 11, further comprising:
a memory module including a plurality of volatile memory devices including the first volatile memory device, wherein each of the volatile memory devices is configured to provide the memory controller with respective refresh information according to a number of identified weak pages of the corresponding volatile memory device.

13. The memory system of claim 12, wherein the memory controller is configured to provide each of the volatile memory devices with auto refresh commands at respective refresh intervals based on the corresponding refresh information provided to the memory controller by the corresponding volatile memory device.

14. The memory system of claim 12, wherein the memory controller is configured to provide the plurality of volatile memory devices with auto refresh commands at the same refresh interval.

15. The memory system of claim 14, wherein the volatile memory devices are configured to perform refresh operations at a timing responsive to the received auto refresh commands and are configured to skip an individual refresh operation based on the refresh information corresponding to the volatile memory device.

16. A memory controller comprising:
a register configured to store refresh information from a first memory device, the refresh information reflecting a number of weak pages of the first memory device; and
a command generation circuit configured to generate auto refresh commands and configured to periodically transmit an auto refresh command to the first memory device at a first refresh interval, the command generation circuit being configured to determine a length of the first refresh interval in response to the refresh information.

17. The memory controller of claim 16,
wherein the memory controller is configured to communicate with a plurality of memory devices,
wherein the register is configured to store refresh information of the plurality of memory devices, including the first memory device, reflecting a number of pages of the plurality of memory devices identified as weak pages, and
wherein, for each of the plurality of memory devices, the command generation circuit is configured to generate and transmit auto refresh commands periodically at a refresh interval corresponding to the respective memory device and determined by the refresh information of the register corresponding to the respective memory device.

18. The memory controller of claim 17, wherein the register is configured to store refresh information of a second memory device, the refresh information of the second memory device reflecting a number of weak pages of the second memory device;
wherein the command generation circuit is configured to periodically transmit an auto refresh command to the second memory device at a second refresh interval, the command generation circuit being configured to determine a length of the second refresh interval in response to the refresh information of the second memory device.

19. The memory controller of claim 18, wherein the first interval is different from the second interval.

20. The memory controller of claim 16,
wherein the memory controller is configured to communicate with a plurality of memory devices,
wherein the register is configured to store refresh information of each of the plurality of memory devices, including the first memory device, the refresh information of each memory device reflecting a number of pages of the plurality of memory devices identified as weak pages of that memory device, and
wherein the command generation circuit is configured to generate and transmit auto refresh commands shared by the plurality of memory devices, the auto refresh commands being transmitted periodically at a refresh interval determined by the command generation circuit, and
wherein the refresh interval is determined by the command generation circuit in response to the refresh information of each of the plurality of memory devices stored.
